(19) United States
(12) Patent Application Publication
(10) Pub. No.: US 2014/0239484 A1
(43) Pub. Date: Aug. 28, 2014

(54) METHOD FOR FORMING SINTERED SILVER COATING FILM, BAKING APPARATUS, AND SEMICONDUCTOR DEVICE

(71) Applicant: Tokyo Electron Limited, Tokyo (JP)

(72) Inventors: Kenji MATSUDA, Yamanashi (JP); Dai SHINOZAKI, Yamanashi (JP); Muneo HARADA, Iwate (JP); Yoshinobu MITANO, Tokyo (JP); Michikazu NAKAMURA, Yamanashi (JP); Itaru IIDA, Yamanashi (JP); Shinjiro WATANABE, Yamanashi (JP)

(73) Assignee: Tokyo Electron Limited, Tokyo (JP)

(21) Appl. No.: 14/184,640

(22) Filed: Feb. 19, 2014

(30) Foreign Application Priority Data
Feb. 22, 2013 (JP) 2013-033476
Aug. 7, 2013 (JP) 2013-163998

(51) Int. Cl. H01L 21/71; F27D 21/00; F27D 11/02; F27D 19/00; H01L 23/373; F27D 7/02

(52) U.S. Cl. CPC H01L 21/71; H01L 23/3736; F27D 7/02; F27D 11/02; F27D 19/00; F27D 21/00
USPC 257/712; 438/584; 219/400; 219/413; 219/401

(57) ABSTRACT

In a method for forming a sintered silver coating film, for use as a heat spreader, on a semiconductor substrate or a semiconductor package, a coating film of an ink or paste containing silver nanoparticles is formed on one surface of the semiconductor substrate or the substrate package. Further, the coating film is sintered by heating the coating film under an atmosphere of a humidity of 30% to 50% RH (30° C.) by a ventilation oven.

### CROSS-REFERENCE TO RELATED APPLICATIONS

This application claims priority to Japanese Patent Applications No. 2013-033476 filed on Feb. 22, 2013, and No. 2013-163998 filed on Aug. 7, 2013, the entire contents of which are incorporated herein by reference.

### FIELD OF THE INVENTION

The present invention relates to a method for forming a sintered silver coating film for use as a heat spreader on a semiconductor substrate or a semiconductor package, a baking apparatus that can be used in forming the sintered silver coating film, and a semiconductor device having the sintered silver coating film.

### BACKGROUND OF THE INVENTION

Generally, a semiconductor chip on which an integrated circuit (especially CPU) that generates a large amount of heat or a power transistor is mounted has an air cooling type or water cooling type heat sink. A semiconductor relay substrate (e.g., a silicon interposer) on which a semiconductor chip that emits a large amount of heat is mounted also has the heat sink.

In order to obtain effective heat radiation by increasing adhesivity and thermal conductivity between the semiconductor substrate that emits a large amount of heat and the heat sink, there is employed a configuration in which a member (generally, a metal plate or a metal film) referred to as a heat spreader is coupled to a heat radiation surface of the semiconductor substrate and a heat sink is connected to the heat spreader directly or via a adhesive layer. As for the material of the heat spreader, copper, copper alloy and aluminum are widely used. The semiconductor substrate and the heat spreader are coupled to each other by a metal paste, a thermally conductive adhesive, a solder, a thermally conductive grease or the like.

In order to effectively maintain an operation of an electronic device on which a semiconductor device that generates a large amount of heat is mounted, it is important to effectively radiate heat generated by the semiconductor device so that a temperature does not exceed an upper limit of a tolerable temperature.

However, the conventional heat spreader structure in which the heat spreader of the metal plate is coupled to the semiconductor substrate via the adhesive layer formed of the metal paste, the thermally conductive adhesive, the solder, the thermally conductive grease or the like is disadvantageous in that the thermal conductivity deteriorates due to generation of voids on the adhesive layer, stress, fatigue or the like to make the reliability and the performance of the cooling function insufficient.

Further, the heat sink is generally mounted on the semiconductor package surrounding the semiconductor chip via the heat spreader. In that case as well, the above problems occur around the heat spreader.

Meanwhile, a high-priced vacuum film forming apparatus is required in the case of forming as the spreader a metal deposition film or a metal sputter film, instead of the metal plate, on the semiconductor substrate.

Therefore, it is preferable to use silver having a highest thermal conductivity, as a heat spreader used in a semiconductor chip, a semiconductor relay substrate, a semiconductor package or the like, and form a sintered coating film on a substrate by coating without using an adhesive substance such as solder or the like in view of obtaining a simple structure of the film forming apparatus.

### SUMMARY OF THE INVENTION

In view of the above, the present invention provides a method for forming a sintered silver coating film, for use as a heat spreader which has excellent adhesivity and thermal conductivity, on a semiconductor substrate or a semiconductor package, a baking apparatus that can be used in the method, and a semiconductor device using the sintered silver coating film.

In accordance with a first aspect of the present invention, there is provided a method for forming a sintered silver coating film, for use as a heat spreader, on a semiconductor substrate or a semiconductor package, the method including: forming a coating film of an ink or paste containing silver nanoparticles on one surface of the semiconductor substrate or the substrate package; and sintering the coating film by heating the coating film under an atmosphere of a humidity of 30% to 50% RH (30° C.) by a ventilation oven.

In accordance with a second aspect of the present invention, there is provided a baking apparatus for baking a coating film of an ink or paste containing silver nanoparticles which is formed on a semiconductor substrate or a semiconductor package, the baking apparatus including: a chamber configured to accommodate the semiconductor substrate or the semiconductor package; a ventilation unit configured to discharge air in the chamber by introducing exterior air into the chamber; a temperature control mechanism configured to control a heating temperature of the semiconductor substrate or the semiconductor package in the chamber to a predetermined baking temperature; and a humidity control mechanism configured to control a humidity in the chamber to be in a range from 30% to 50% RH (30° C.).

In accordance with a third aspect of the present invention, there is provided a semiconductor device including: a sintered silver coating film formed on a semiconductor substrate or a semiconductor package by the method for forming the sintered silver coating film; and a heat radiation portion coupled to the sintered silver coating film.

### BRIEF DESCRIPTION OF THE DRAWINGS

The objects and features of the present invention will become apparent from the following description of embodiments, given in conjunction with the accompanying drawings, in which:

FIG. 1 is a cross sectional view showing a configuration example of a semiconductor device in accordance with an embodiment of the present invention;

FIG. 2 is a perspective view showing a film forming process in the embodiment of the present invention;

FIG. 3 is a cross sectional view showing a state where a sintered silver coating film is formed on a semiconductor substrate by the film forming process;

FIG. 4 is a cross sectional view showing a configuration example of a baking apparatus that can be used for a baking process;

FIG. 5 is a cross sectional view showing another configuration example of the baking apparatus that can be used for the baking process;

FIG. 6 is a view for explaining a temperature condition in a sintering process in a test example;

FIGS. 7A to 7C are perspective views showing a test of evaluating an adhesivity of the sintered silver coating film (peel test) in the test example;

FIG. 8 shows an evaluation result of adhesivity of the sintered silver coating film in each sample in the case of setting humidity of the sintering process as a parameter in the test example;

FIG. 9 shows scanning electron microscope images of cross section states and surface states of the sintered silver coating film in each sample in the case of setting the humidity of the sintering process as the parameter in the test example;

FIG. 10 is a view for explaining relationship between the humidity of the sintering process and an electrical resistivity of the sintered silver coating film in the test example;

FIG. 11 is a graph showing relationship between an electrical resistivity and a thermal conductivity based on the Wiedemann-Franz law;

FIG. 12 shows an evaluation result of adhesivity of the sintered silver coating film in each sample in the case of setting a film thickness of the sintered silver coating film as a parameter in the test example;

FIG. 13 shows an evaluation result of adhesivity of the sintered silver coating film in each sample in the case of setting a sintering condition as a parameter in the test example;

FIG. 14 shows scanning electron microscope images of cross section states of the sintered silver coating film in each sample in the case of setting the sintering condition as the parameter in the test example;

FIG. 15 is a block diagram showing still another configuration example of the baking apparatus;

FIG. 16 is a view for explaining a technique for controlling a moisture content for the baking process to a constant level by referring to a psychrometric chart in the baking apparatus shown in FIG. 15;

FIG. 17 is a block diagram showing still another configuration example of the baking apparatus; and

FIG. 18 is a block diagram showing still another configuration example of the baking apparatus.

### DETAILED DESCRIPTION OF THE EMBODIMENTS

In the method for forming a sintered silver coating film of the present invention, the humidity in a sintering process may be in a range from 35% to 45% RH (30° C.). With the above humidity condition, the sintered silver coating film for use as a heat spreader which has excellent adhesivity and thermal conductivity can be formed on a semiconductor substrate or a semiconductor package.

Further, a heating temperature in the sintering process may be equal to or higher than 100° C. Accordingly, the sintered silver coating film having excellent adhesivity can be obtained.

Further, a heating temperature in the sintering process may be in a range from 100° C. to 250° C. Accordingly, in the case of using, e.g., a resin material that does not cause thermal deformation and thermal degradation under about 250° C. or less, in a semiconductor package, the sintered silver coating film for use as a heat spreader which has excellent adhesivity and thermal conductivity can be formed.

In one embodiment, the ink or paste may contain silver ultrafine particles coated with alkylamine-based protective molecules. With the above configuration, the sintered silver coating film for use as a heat spreader which has excellent adhesivity and thermal conductivity can be formed by low-temperature baking of the coating film of the ink or the paste.

In one embodiment of the baking apparatus of the present invention, the ventilation unit may include: a first port through which the exterior air is introduced into the chamber and a second port through which the air in the chamber is exhausted, the first port and the second port provided at different walls of the chamber; and a fan configured to move air from the first port to the second port in the chamber. With the above configuration, the ventilation efficiency is increased, and the baking time is reduced. Also, a temperature and humidity in an atmosphere in the chamber become uniform, so that the uniformity and the reproducibility of the sintering process can be improved. Further, the reliability of the physical property (the adhesivity and the thermal conductivity) of the sintered silver coating film can be improved.

Further, in one embodiment, the temperature control mechanism may include a heater configured to preheat the exterior air before the exterior air is introduced into the chamber and a heater configured to heat air in the chamber. Furthermore, the temperature control mechanism may include: a temperature measuring unit configured to measure a temperature of an atmosphere in the chamber; and a temperature control unit configured to control a heat radiation amount of the heater such that a measured temperature value obtained by the temperature measuring unit becomes equal to a set temperature value. With the above configuration, it is possible to ensure accuracy of the baking temperature and improve the uniformity and the reproducibility of the sintering process. Further, the reliability of the physical property (the adhesivity and the thermal conductivity) of the sintered silver coating film can be improved.

Further, in one embodiment, the humidity control mechanism may include: a dry air generation unit configured to generate dry air; a humidifier configured to humidify the air generated by the dry air generation unit before the air is introduced into the chamber; a humidity measuring unit configured to measure humidity in the chamber; and a humidity control unit configured to control an output of at least one of the dry air generation unit and the humidifier such that a measured humidity value obtained by the humidity measuring unit becomes equal to a set humidity value. With the above configuration, it is possible to accurately manage humidity in an atmosphere of the chamber and improve the uniformity and the reproducibility of the sintering process. Further, the reliability of the physical property (the adhesivity and the thermal conductivity) of the sintered silver coating film can be improved.

Further, in another embodiment, the humidity control mechanism may include: a dry air generation unit configured to generate dry air; a humidifier configured to humidify the air generated by the dry air generation unit before the air is introduced into the chamber; a moisture content measuring unit configured to measure a moisture content of the air humidified by the humidifier; and a humidity control unit configured to control an output of at least one of the dry air generating unit and the humidifier such that a measured moisture content value obtained by the moisture content measuring unit becomes equal to a set moisture content value. With the above configuration, it is possible to accurately manage humidity in an atmosphere in the sintering process and improve the uniformity and the reproducibility of the sintering process. Further, the reliability of the physical property (the adhesivity and the thermal conductivity) of the sintered silver coating film can be improved.

Further, in still another embodiment, the humidity control mechanism may include: a dry air generation unit configured to generate dry air; a vaporizer configured to vaporize water to generate mixed gas with the dry air from the dry air generation unit; a first flow rate control valve configured to control a flow rate of the dry air supplied from the dry air generation unit to the vaporizer; a second flow rate control valve configured to control a flow rate of the water supplied to the vaporizer; a temperature-humidity sensor configured to measure a temperature and a humidity of the mixed gas generated by the vaporizer; and a humidity control unit configured to control at least one of flow rates of the dry air and the water supplied to the vaporizer through the first and the second flow rate control valve such that a weight ratio between the water and the air in the mixed gas becomes a set value, based on a measured temperature value and a measured humidity value obtained by the temperature-humidity sensor. With the above configuration, it is possible to accurately manage humidity in an atmosphere of the chamber and improve the uniformity and the reproducibility of the sintering process. Further, the reliability of the physical property (the adhesivity and the thermal conductivity) of the sintered silver coating film can be improved.

Further, in one embodiment, the humidity control unit includes an air duct through which the air humidified by the humidifier is moved to the chamber. With the above configuration, the humidity in an atmosphere of the chamber can be more accurately and effectively controlled.

The semiconductor substrate of the present invention is, e.g., a semiconductor chip, a semiconductor wafer, a semiconductor relay substrate (e.g., a silicon interposer). The semiconductor substrate is typically made of silicon. The sintered silver coating film of the present invention may be properly formed on the surface of the silicon substrate which is exposed in a bare state. Moreover, the surface of the semiconductor substrate may be coated with an inorganic film containing silicon, e.g., silicon oxide (SiO₂) layer, a silicon nitride (SiN) layer or the like. The sintered silver coating film of the present invention may be properly formed on the inorganic film. Furthermore, a metal layer such as a Cu layer, an Au layer or the like may be formed on the surface of the semiconductor substrate.

The semiconductor package of the present invention is, e.g., a ceramic package or a resin package. The ceramic package has a frame body and an upper cover body made of a ceramic material such as alumina, aluminum nitride, mullite or the like. A semiconductor device or a semiconductor substrate (semiconductor chip) is provided and sealed inside the ceramic package. The resin package has a resin case where semiconductor chips are disposed and a resin cover for covering the resin case. The semiconductor chips are sealed and packaged therein. As for the resin forming the resin package, a resin filled with a filler having a good electrical insulation property and a high thermal conductivity, e.g., aluminum oxide, aluminum nitride, silicon nitride, boron nitride, silica (silicon oxide) or the like, is properly used. An inorganic layer containing silicon such as a silicon oxide (SiO₂) layer, a silicon nitride (SiN) layer or the like, or a metal layer such as a Cu layer or an Au layer may be formed thereon may be formed on the surface of the semiconductor packages on which the sintered silver coating film is formed.

Hereinafter, an embodiment of the present invention will be described in detail with reference to the accompanying drawings.

(Semiconductor Device in Accordance with Embodiment)

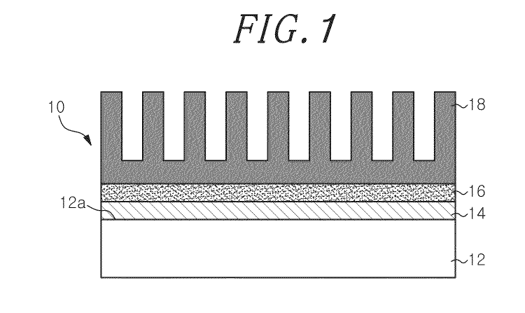

FIG. 1 shows a configuration example of a semiconductor device in accordance with an embodiment of the present invention. In an illustrated semiconductor device 10, a semiconductor substrate 12 is a semiconductor relay substrate or a bare semiconductor chip having an integrated circuit or wiring (not shown). A sintered silver coating film 14 is formed on one surface (heat radiation surface) 12a of the semiconductor substrate 12 by using a baking apparatus and a method for forming a sintered silver coating film in accordance with the present invention which will be described later. Further, heat radiation fins 18 made of, e.g., copper or aluminum, are coupled onto the sintered silver coating film 14 for use as a heat spreader via an adhesive layer 16. The adhesive layer 16 is made of, e.g., a metal paste, a thermally conductive adhesive, a solder or a thermally conductive grease. In another configuration of the heat radiation part, the adhesive layer 16 may be omitted. In other words, the heat radiation fins 18 may be directly installed on the sintered silver coating film 14.

In this semiconductor device 10, the heat generated by the semiconductor substrate 12 is effectively emitted through the sintered silver coating film 14 since the sintered silver coating film 14 has excellent adhesivity and thermal conductivity with respect to the heat radiation surface 12a of the semiconductor substrate 12. Accordingly, the integrated circuit formed on the semiconductor substrate can stably operate within a range of a tolerable temperature.

The semiconductor substrate 12 serving as a workpiece to which the method for forming a sintered silver coating film or the baking apparatus of the present embodiment is applied may be the semiconductor chip or the semiconductor relay substrate in a product state. Or, the semiconductor substrate 12 may also be a semiconductor wafer in a state before semiconductor devices are completed.

(Method for Forming a Sintered Silver Coating Film and Baking Apparatus in Accordance with Embodiment)

The method for forming a sintered silver coating film of the present embodiment includes a coating process (1) as a first process and a sintering process (2) as a second process.

(1) First, a coating film of an ink or a paste containing silver nanoparticles (silver ultrafine particles coated with alkylamine-based protective molecules) is formed on the heat radiation surface 12a of the semiconductor substrate 12.

(2) Next, the coating film is sintered by heating under an atmosphere of a humidity higher than or equal to 30% RH and lower than or equal to 50% RH (30° C.) by a ventilation oven.

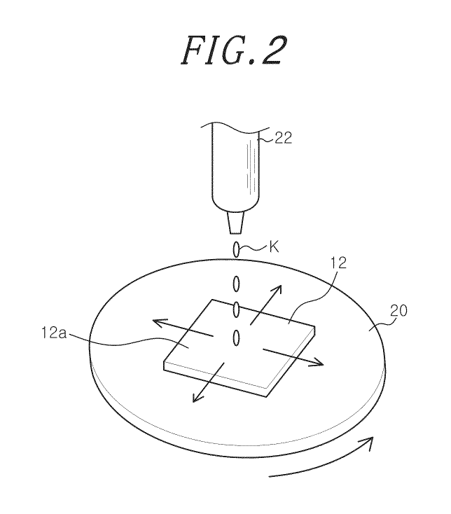

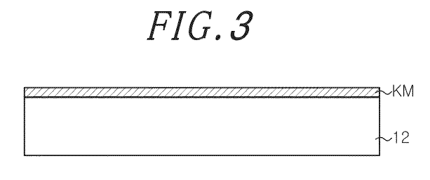

FIG. 2 shows the coating process (1) using a spin coating method. As illustrated, the semiconductor substrate with the heat radiation surface 12a facing upward is mounted and fixed onto a rotatable circular plate 20. Thereafter, ink K is dropped from a dispensing opening of a dispensing unit 22 to a central portion of the semiconductor substrate 12 while the semiconductor substrate 12 and the rotatable circular plate 20 are spin-rotated as one unit. As a consequence, liquid droplets of the ink K are diffused from the central portion toward the peripheral portion by the centrifugal force of the spin rotation, and, as shown in FIG. 3, a coating film KM is formed with a uniform film thickness on the semiconductor substrate 12. Here, the ink K contains silver nanoparticles (silver ultrafine particles coated with alkylamine-based protective molecules). Therefore, the coating film KM formed on the semiconductor substrate 12 also contains the same silver nanoparticles (silver ultrafine particles coated with alkylamine-based protective molecules).

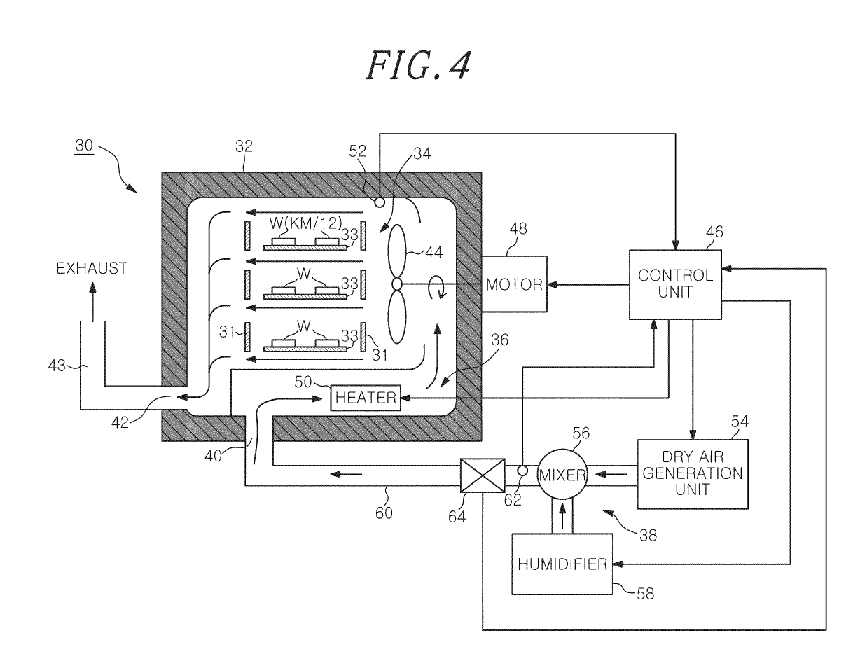

FIG. 4 shows a configuration example of a baking apparatus of the present embodiment which can be used in the sintering process (2). This baking apparatus 30 is configured as a ventilation oven for performing a baking process while exchanging indoor air with exterior air. More specifically, the baking apparatus 30 includes a chamber 32 capable of accommodating a plurality of workpieces W simultaneously in a baking room provided with, e.g., a partition wall or a rectifying plate 31 and a stage 33, and the semiconductor substrate 12 having, on one surface thereof, an ink coating film KM containing silver nanoparticles formed by the coating process (1) can be loaded in and unloaded from the chamber 32 as the workpiece W (KM/12). Further, the baking apparatus 30 includes a ventilation unit 34 for exhausting gas from the chamber 32 while introducing exterior air into the chamber 32, a temperature control mechanism 36 for controlling an atmosphere in the chamber 32 to a predetermined baking temperature, and a humidity control mechanism 38 for controlling a humidity in the chamber 32 to a set value ranging from 30% to 50% RH (30° C.). In the present embodiment, the exterior air refers to air that has not yet been introduced into the chamber 32.

The ventilation unit 34 includes an air inlet port 40 and an exhaust port 42 which are provided at different walls of the chamber 32, e.g., the bottom wall and the sidewall, respectively, and a fan 44 for moving air from the air inlet port 40 toward the exhaust port 42 while stirring the air in the chamber 32. The fan 44 is driven by a motor 48 under the control of a control unit 46. As will be described later, the air inlet port 40 is configured to introduce the humidified air having controlled moisture content into the chamber 32. The exhaust port 42 is an outlet through which gas in the chamber 32 is exhausted and is open to the atmosphere via an exhaust line 43 or connected to an exhaust duct (not shown) of a factory.

The temperature control mechanism 36 includes a heater for heating the air introduced into the chamber 32 through the air inlet port 40, a temperature sensor 52 for measuring a temperature in an atmosphere in the chamber 32, and the control unit 46 for controlling the heat radiation amount of the heater 50 such that a temperature value measured by the temperature sensor 52 becomes equal to a set temperature value. The heater 50 may be any heater that heats ambient air by emitting heat, e.g., an electric heater, a carbon fiber heater or the like.

The humidity control mechanism 38 includes: a dry air generation unit 54 for generating dry air in the outside the chamber 32; a humidifier 58 for humidifying the dry air discharged from the dry air generation unit 54 through a mixer 56 before the dry air is introduced into the chamber 32; a moisture content sensor 62 and a flow rate sensor 64 provided in an air duct 60 which forms an airtight air flow path from the outlet of the mixer 56 to the air inlet port 40; and the control unit 46. The moisture content sensor 62 and the flow rate sensor 64 measure a moisture content and a flow rate of the humidified air flowing in the duct 60, respectively. The control unit 46 calculates a moisture content per unit volume (measurement value) of the humidified air introduced into the chamber 32 based on the measurement value signal from the moisture content sensor 62 and the flow rate sensor 64, and controls the output of at least one of the dry air generation unit 54 and the humidifier 58 such that the moisture content per unit volume (measurement value) becomes equal to a set value.

Further, the moisture content sensor 62 may be, e.g., an electrical resistance-type moisture meter, an electronic moisture meter using electrical changes of hygroscopic materials, an infrared (absorption) moisture meter using absorption of infrared rays or the like.

In this baking apparatus 30, the humidified air whose moisture content per unit volume has been controlled to a constant level by the humidity control mechanism 38 is introduced from the air inlet port 40 into the chamber 32 through the air duct 60. The humidified air introduced into the chamber 32 is heated by the heater 50 before it is introduced into the baking room, passes through the baking room toward the exhaust port 42 while dragging a gas other than the air by the thrust of the fan 44, and then is discharged to the outside of the chamber 32 through the exhaust port 42.

During the baking process, the ventilation unit 34, the temperature control mechanism 36, and the humidity control mechanism 38 having the above-described configurations perform respective functions or operations under the control of the control unit 46. Hence, an atmosphere in the baking room of the chamber 32 is controlled to a set constant temperature and a set constant humidity. Specifically, the baking temperature for the sintering process (2) is controlled to be equal to or higher than 100° C., preferably equal to or higher than 100° C. and equal to or lower than 250° C., and more preferably equal to or higher than 100° C. and equal to or lower than 200° C. Further, the humidity is controlled within a range from 30% to 50% RH (30° C.) and preferably within a range from 35% RH to 45% RH (30° C.).

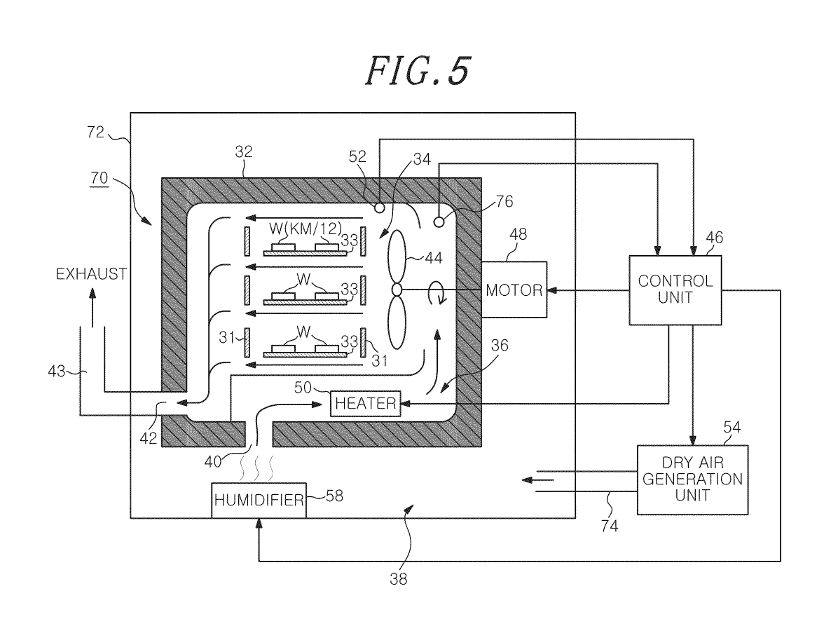

FIG. 5 shows a modification of the baking apparatus of the present embodiment. In FIG. 5, like reference numerals are used for like parts having the same configurations or functions as those of the baking apparatus of FIG. 4.

The chamber 32 of the baking apparatus 70 is disposed, in a state where the air inlet port 40 is open, in an air-conditioned room 72 that is a closed space. In the air-conditioned room 72, the dry air from the dry air generation unit 54 flows in through the air duct 74 and the humidifier 58 is disposed near the air inlet port 40. Accordingly, the dry air from the dry air generation unit 54 is humidified mainly near the air inlet port 40 (inside as well as outside the chamber 32) and heated by the heater 50 in the chamber 32. The humidity control mechanism 38 of the baking apparatus 70 has a humidity sensor 76 disposed in the chamber 32. The control unit 46 controls the output of at least one of the dry air generation unit 54 and the humidifier 58 such that a humidity value measured by the humidity sensor 76 becomes equal to a set value.

In this baking apparatus 70 as well, during the baking process, the ventilation unit 34, the temperature control mechanism 36 and the humidity control mechanism 38 perform respective functions or operations under the control of the control unit 46. Accordingly, an atmosphere in the baking room of the chamber 32 is controlled to a set constant temperature and a set constant humidity. Specifically, the baking temperature for the sintering process (2) is controlled to be equal to or higher than 100° C., preferably equal to or higher than 100° C. and equal to or lower than 250° C., and more preferably equal to or higher than 100° C. and equal to or lower than 200° C. Further, the humidity is controlled within a range from 30% to 50% RH (30° C.) and preferably within a range from 35% RH to 45% RH (30° C.).

### Test Example

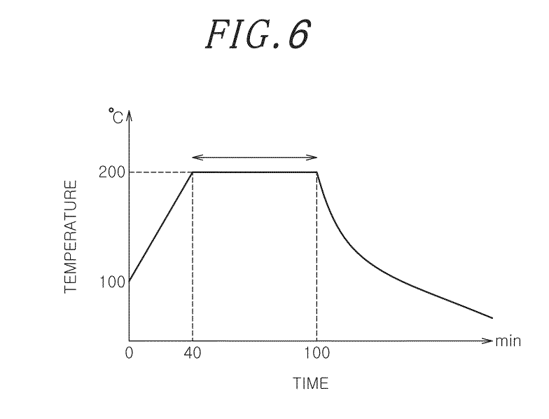

Hereinafter, a test example of the present invention will be described with reference to FIGS. 6 to 14. Especially, there will be described in detail the baking conditions (sample type, humidity for baking, film formation thickness, baking temperature) in the method for forming a sintered silver coating film of the test example, evaluation of adhesivity of the formed sintered silver coating film and conductivity of the formed sintered silver coating film.

First, dispersion solution of coated silver ultrafine particles used in the test example was manufactured by a manufacturing method described in the test example 10 (paragraph 0084) of Japanese Patent Application Publication No. 2010-265543. In this regard, In the method for manufacturing dispersion solution of coated silver ultrafine particles disclosed in paragraph 84 of Japanese Patent Application Publication No. 2010-265543, 5.78 g (57.1 mmol) of n-hexylamine, 0.885 g (4.77 mmol) of n-dodecylamine, 3.89 g (38.1 mmol) of N,N-dimethyl-1,3-diaminopropane and 0.251 g (0.889 mmol) of oleic acid (Tokyo Chemical Industry, >85.0%) were mixed, 7.60 g (25.0 mmol) of silver oxalate was added to the mixed solution and stirred for about 1 hour to form an oxalate ion-alkylamine-alkyldiamine-silver complex compound, and the complex compound was changed to a viscous solid. Further, when this was stirred for 10 minutes while heating at 100° C., a reaction accompanied by foaming of carbon dioxide was completed, and the reaction mixture was changed to a suspension having a blue glossy color. 10 mL of methanol was added thereto, a precipitate obtained by centrifugal separation was separated, 10 ml of methanol was again added and the precipitate was stirred to obtain a precipitate of coated silver nanoparticles by centrifugal separation. A mixed solvent of n-octane and n-butanol (volume ratio 4:1) was added to the precipitate of coated silver nanoparticles and then stirred to obtain a dispersion in which the coated silver nanoparticles favorably dispersed at a concentration of 50% by weight.

Meanwhile, five types of semiconductor chips of 30 mm×30 mm were prepared as the semiconductor substrate 12 in the test example. Specifically, there were prepared a bare semiconductor chip (Si bare chip) 12A formed of a silicon substrate, a semiconductor chip (SiO₂/Si chip) 12B having a silicon oxide film (SiO₂ film) formed at one surface thereof, a semiconductor chip (SiN/Si chip) 12C having a silicon nitride film (SiN film) formed at one surface thereof, a semiconductor chip (Cu/Si chip) 12D having a Cu film formed at one surface thereof, and a semiconductor chip (Au/Si chip) 12E having an Au film formed at one surface thereof.

In the test example of the present invention, the above-described spin coating method (see FIG. 2) was used in the coating process (1). Specifically, a coating film KM was formed on each of the surfaces of the Si bare chip, the SiO₂/Si chip, the SiN/Si chip, the Cu/Si chip and the Au/Si chip (Si surface, SiO₂ surface, SiN surface, Cu surface, and Au surface) by the spin coating method using dispersion solution of coated silver ultrafine particles.

Further, the baking apparatus 70 having the configuration shown in FIG. 5 was used for the sintering process (2) in the test example of the present invention. Moreover, the Si bare chip, the SiO₂/Si chip, the SiN/Si chip, the Cu/Si chip, and the Au/Si chip, each having the coating film KM formed thereon, were baked under the same conditions by the baking apparatus 70.

FIG. 6 shows a temperature condition for the baking process in the test example of the present invention. As illustrated, the temperature was increased from 100° C. to 200° C. for 40 minutes, and maintained at 200° C. for 60 minutes, and then decreased to about 80° C. for about 80 minutes. Thereafter, each of the semiconductor chips 12 was unloaded to the outside of the baking apparatus.

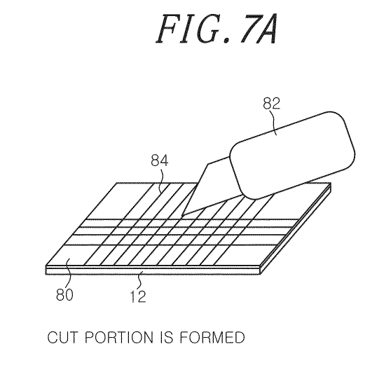

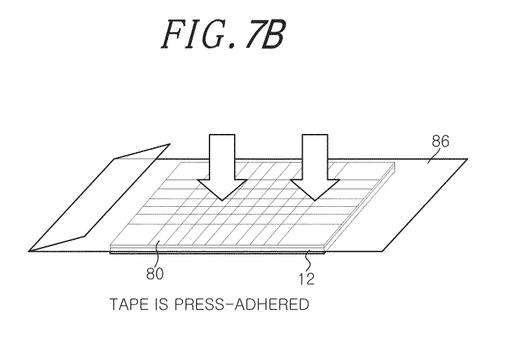

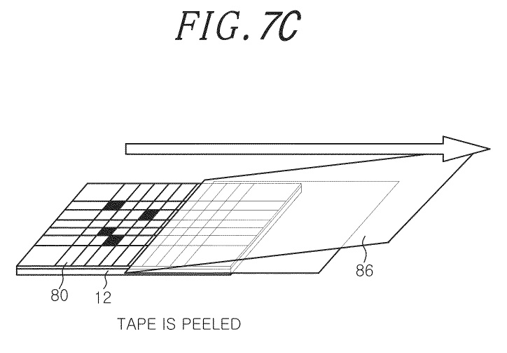

Further, the adhesivity of the sintered silver coating film 80 formed on each semiconductor chip 12 (adhesivity of the sintered silver coating film to the chip) was evaluated by a peel test in conformity to the cross cut peel test described in JIS (Japanese Industrial Standards)-K5400. FIGS. 7A to 7C show contents and sequences of the peel test.

First, as shown in FIG. 7A, incisions 84 are formed on a sintered silver coating film 80 on a semiconductor chip 12 by using a cutter knife 82 so that an edge of the cutter knife 82 penetrates through the sintered silver coating film 80 and reaches the semiconductor chip 12. The incisions 84 are formed in a grid pattern spaced at an interval of 1 mm in two orthogonal directions, so that the grid pattern formed of 100 square sections (mass) is formed on the sintered silver coating film 80.

Next, as shown in FIG. 7B, an adhesive tape (Scotch Tape manufactured by 3M: 610-1PK, tape strength 3.7 N/cm) 86 was press-adhered to the sintered silver coating film 80 on the semiconductor chip 12. Then, as shown in FIG. 7C, the adhesive tape 86 adhered to the sintered silver coating film 80 on the semiconductor chip 12 was peeled by pulling the end portion thereof to one direction. Next, the number or the ratio of unpeeled sections (mass) of the sintered silver coating film 80 was counted by eyes.

As a reference for evaluating the adhesivity between the semiconductor chip 12 and the sintered silver coating film 80 in each sample, the case where the peeling of the sintered silver coating film 80 from the semiconductor chip 12 was not found in all the 100 sections (mass) was set to 100%. When any of the 100 sections (mass) was peeled, the ratio (%) of the unpeeled sections (mass) was obtained.

In the test example, the thermal conductivity of the sintered silver coating film 80 was calculated based on the Wiedemann-Franz law, as will be described later, from the surface resistivity measured by four probe sheet resistivity meters and the electrical resistivity (volume resistivity) obtained from the film thickness of the sintered silver coating film.

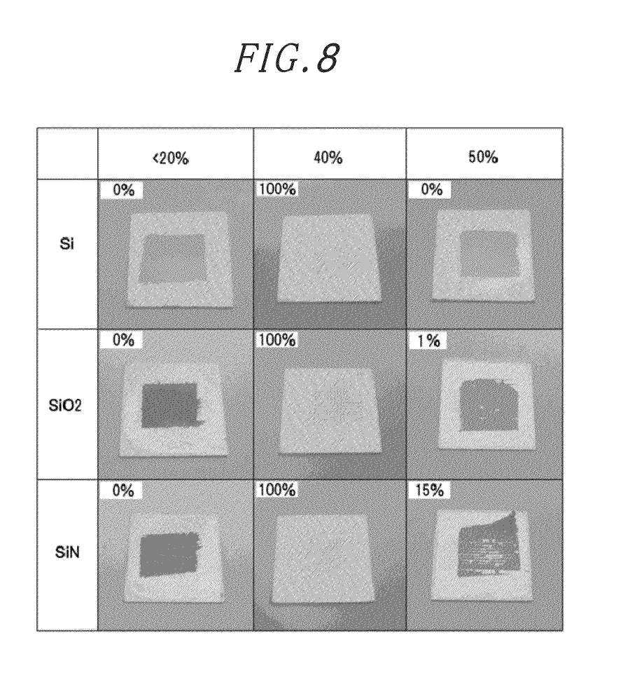

Table 1 and FIG. 8 show the evaluation result of the adhesivity of the sintered silver coating films obtained by selecting three humidity conditions, i.e., <20%, 40%, and 50%, for the baking process in each of the samples of the Si bare chip, the SiO₂/Si chip and the SiN/Si chip.

TABLE 1

| | <20% | 40% | 50% |
|---|---|---|---|
| Si | 0% | 100% | 0% |
| SiO₂ | 0% | 100% | 1% |
| SiN | 0% | 100% | 15% |

As shown in Table 1 and FIG. 8, in the case where the humidity of the baking atmosphere in the baking of the coating film was set to 40%, all the 100 sections (mass) were not peeled in the peel test in all the samples of the Si bare chip, the SiO₂/Si chip, and the SiN/Si chip.

The following is the outline of the result obtained by changing the humidity of the baking atmosphere by the present inventors in the baking of the coating film KM in the test example.

(a) In the case of 10% humidity, the adhesivity was completely poor.

(b) In the case of 20% humidity, the adhesivity was slightly improved compared to the case of 10%.

(c) In the case of 30% to 40% humidity, the adhesivity was highest.

(d) In the case of 50% or above humidity, the adhesivity was decreased.

The humidity of the baking atmosphere in the baking of the coating film KM is preferably 30% to 50% and more preferably about 40%. When the humidity is excessively low or high, desired adhesivity of the sintered silver coating film is not obtained. It has been found that the adhesivity of the sintered silver coating film is greatly affected by the humidity.

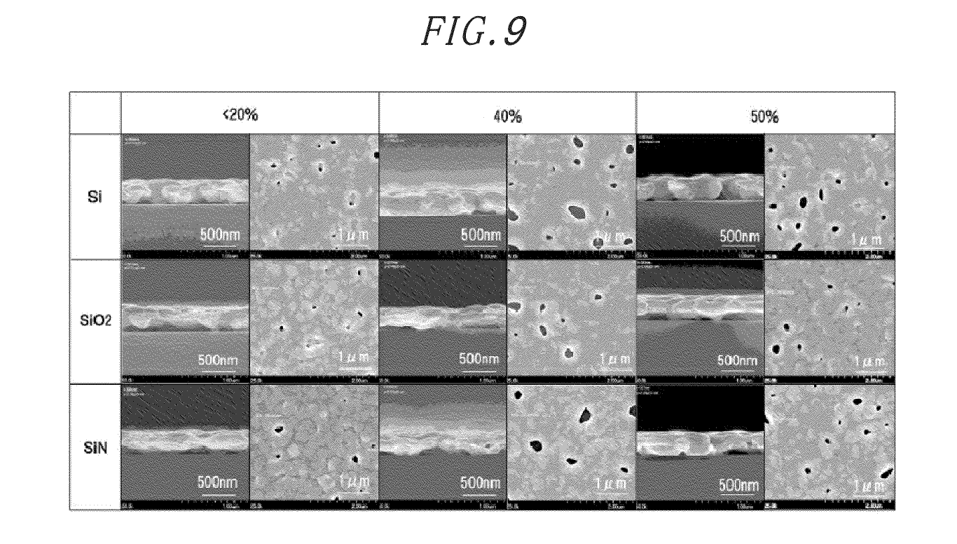

FIG. 9 shows scanning electron microscope images representing the cross section states and the surface states of the sintered silver coating film obtained by selecting three humidity conditions, i.e., <20%, 40% and 50%, for the baking process in each of the samples of the Si bare chip, the SiO₂/Si chip, and the SiN/Si chip. Table 2 shows the electrical resistivity (Q·cm) and the film thickness (t(nm)) of the sintered silver coating film obtained from the scanning electron microscope images.

TABLE 2

| | | | 40% | | 50% | |
|---|---|---|---|---|---|---|
| | <20% | | | ρ | | ρ |
| | t (nm) | ρ(μΩ · cm) | t (nm) | (μΩ · cm) | t (nm) | (μΩ · cm) |
| Si | 384 | 2.74 | 349 | 2.66 | 361 | 2.60 |
| SiO₂ | 381 | 2.71 | 337 | 2.45 | 383 | 2.64 |
| SiN | 389 | 2.76 | 345 | 2.53 | 357 | 2.58 |

As clearly seen from FIG. 9 and Table 2, even if the humidity of the baking atmosphere was changed, the particle diameter of the sintered silver coating film was within a range from 200 nm to 600 nm, and no remarkable change was seen in the surface state. If the baking temperature is further increased to, e.g., 300° C. or above, the surface state of the sintered silver coating film becomes more uniform.

In all the samples of the Si bare chip, the SiO₂/Si chip and the SiN/Si chip, when the humidity of the sintering atmosphere was 40%, no peeling was found at all the 100 sections (mass) in the peel test of the sintered silver coating film formed on the chip surface.

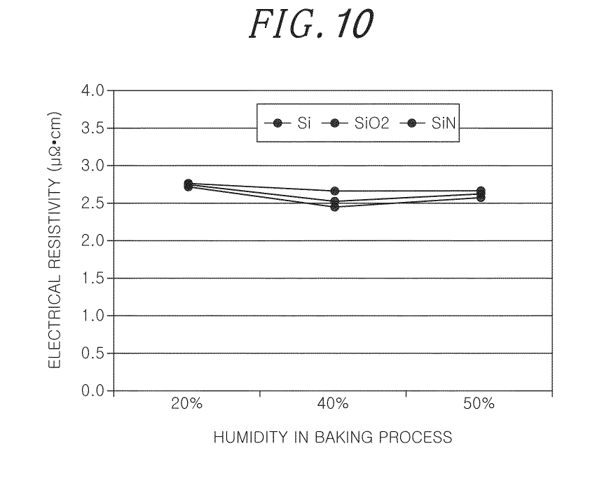

As shown in FIGS. 9 and 10 and Table 2, even if the humidity of the atmosphere in the baking process was changed, the electrical resistivity (Q·cm) of the sintered silver coating film was not greatly changed. When the humidity of the baking atmosphere was 40%, the electrical resistivity (Ω·cm) of the sintered silver coating film was about 2.4 μΩ·cm to 2.7 μΩ·cm.

The thermal conductivity (λ)(W/(m·K)) of the sintered silver coating film can be estimated from the electrical resistivity (ρ) (Ω·cm) of the sintered silver coating film.

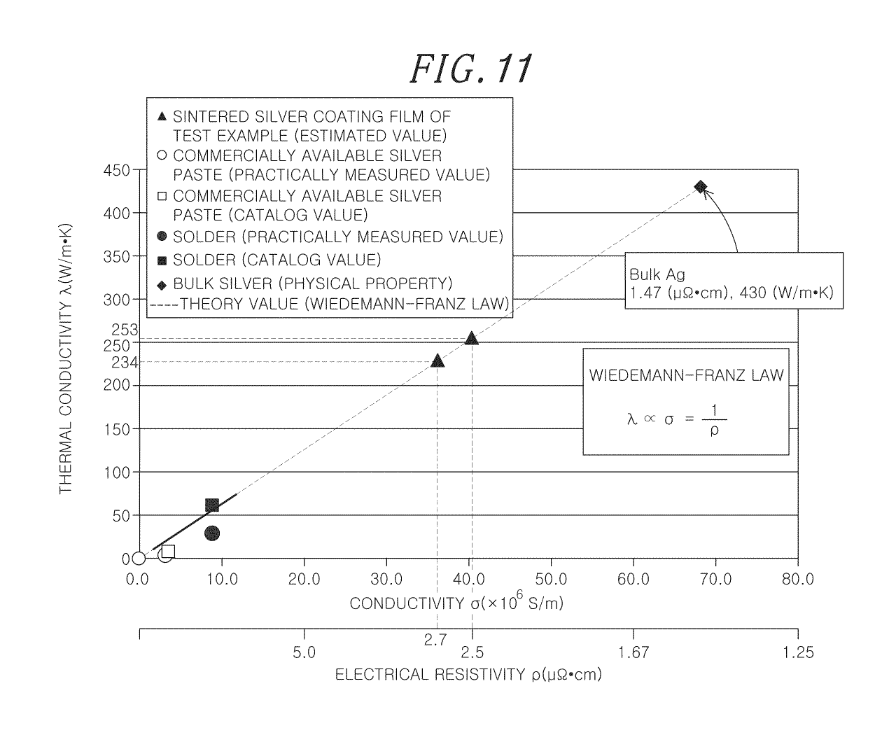

For example, in the case of using the Wiedemann-Franz law (λ∝σ=1/ρ) on the assumption that bulk silver has an electrical resistivity ρ(μΩ·cm) of 1.47 and a thermal conductivity λ(W/m·K) of 430, as shown in FIG. 11, the thermal conductivity λ(W/m·K) of the sintered silver coating film is 234 to 253 (estimated value) when the electrical resistivity ρ(μΩ·cm) of the sintered silver coating film in the test example is 2.5 to 2.7.

The thermal conductivity (λ) (W/m·K) of 234 to 253 of the sintered silver coating film of the test example shown in Table 2 and FIGS. 9 and 10 is considerably large compared to a thermal conductivity of about 10 of a commercially available silver paste, and a thermal conductivity of about 50 of a commercially available solder. Thus, it is clear that the thermal conductivity of the sintered silver coating film is excellent. Accordingly, the sintered silver coating film can be used as a heat spreader having a low thermal resistance and a good heat radiation effect.

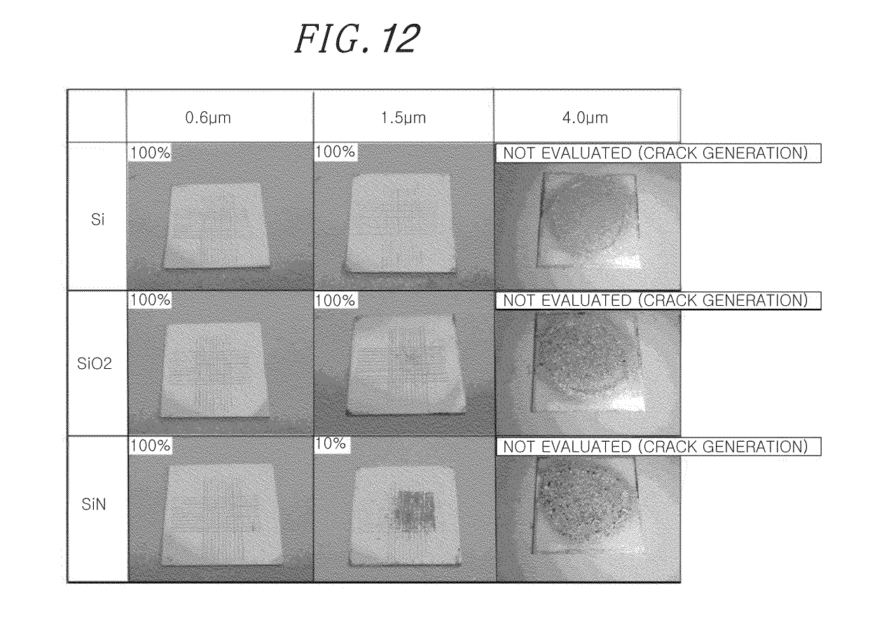

FIG. 12 and Table 3 are for explaining the result of evaluating the adhesivity of the sintered silver coating film depending on the film thickness condition of the sintered silver coating film in the test example of the present invention. Here, the result of the peel test obtained by selecting three film thicknesses, i.e., about 0.6 μm, 1.5 μm, and 4.0 μm, of the sintered silver coating film in each of samples of the Si chip, the SiO₂/Si chip, and the SiN/Si chip are shown.

TABLE 3

| | 0.6 μm | 1.5 μm | 4.0 μm |
|---|---|---|---|
| Si | 100% | 100% | Not evaluated |
| | | | (crack generation) |
| SiO₂ | 100% | 100% | Not evaluated |
| | | | (crack generation) |
| SiN | 100% | 10% | Not evaluated |
| | | | (crack generation) |

As shown in FIG. 12 and Table 3, in the SiN/Si chip on which the sintered silver coating film having a thickness of 1.5 μm was formed, no peeling appeared at 10 sections among 100 sections (mass) as a result of the peel test. In other words, the ratio of the unpeeled section was 10%. In the Si bare chip and the SiO₂/Si chip on which the sintered silver coating film having a thickness of 1.5 μm was formed, and in the Si chip, the SiO₂/Si chip and the SiN/Si chip on which the sintered silver coating film having a thickness of 0.6 μm was formed, no peeling appeared at all of the 100 sections (mass) as a result of the peel test. In other words, the ratio of the unpeeled section was 100%.

Further, in the case of the Si chip, the SiO₂/Si chip and the SiN/Si chip on which the sintered silver coating film having a thickness of 4.0 μm was formed, cracks were generated during the baking of the spin coating film and, thus, it was not possible to normally form a sintered silver coating film. Accordingly, the peel test was not evaluated.

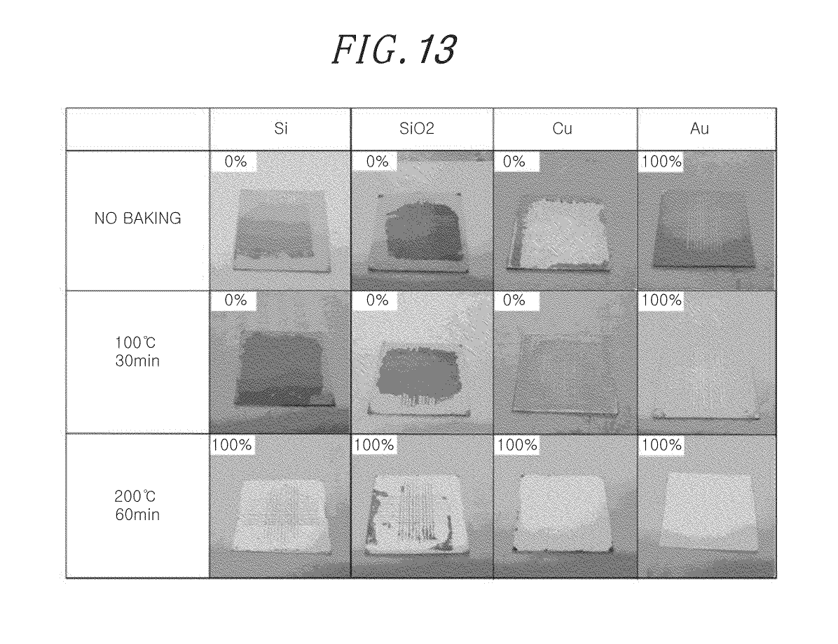

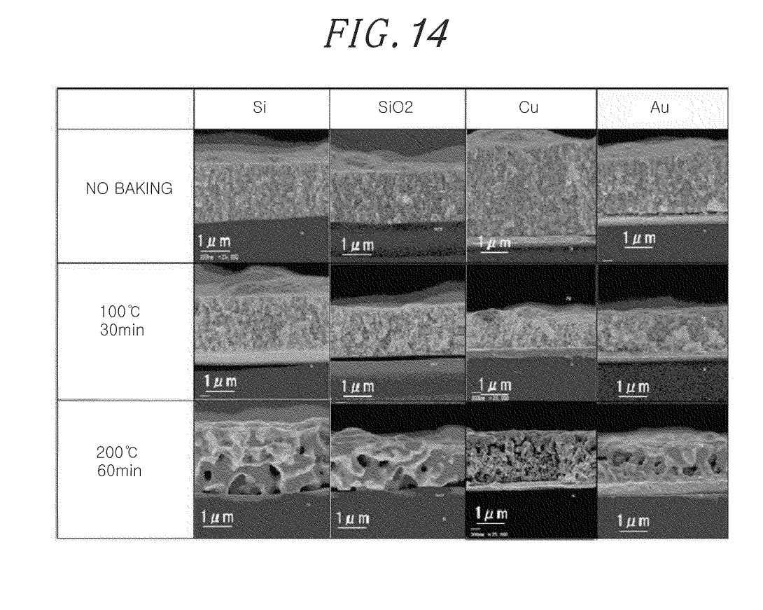

FIGS. 13 and 14 respectively show the results of the peel test and scanning electron microscope images representing the cross sections of the sintered silver coating film, which are obtained by selecting three baking conditions, i.e., ┌no baking┐, ┌100° C.┐, 30 mini and ┌200° C., 60 min┐, in each of the samples of the Si bare chip, the SiO₂/Si chip, the SiN/Si chip, the Cu/Si chip and the Au/Si chip in the test example of the present invention. Table 4 corresponds to FIG. 13.

As shown in FIG. 13 and Table 4, in the Si bare chip, the SiO₂/Si chip and the Cu/Si chip whose coating films (KM) were not baked and in the Si bare chip, and the SiO₂/Si chip and the Cu/Si chip whose coating films (KM) were baked at 100° C. for 30 minutes, the peeling appeared at all of the 100 sections (mass) as a result of the peel test. In other words, the ratio of the unpeeled section was 0%.

Further, in the Au/Si chip whose coating film (KM) was not baked, in the Au/Si chip whose coating film (KM) was baked at 100° C. for 30 minutes, and in the Si bare chip, the SiO₂/Si chip, the Cu/Si chip and the Au/Si chip whose coating films (KM) were baked at 200° C. for 60 minutes, no peeling appeared at all of the 100 sections (mass) as a result the peel test. In other words, the ratio of the unpeeled section was 100%.

By baking the coating film (KM) at 200° C. for 60 minutes, the good chip adhesivity can be ensured in all of the Si bare chip, the SiO₂/Si chip, the Cu/Si chip, and the Au/Si chip.

TABLE 4

| | Si | SiO₂ | Cu | Au |
|---|---|---|---|---|
| No baking | 0% | 0% | 0% | 100% |
| 100° C., 30 min | 0% | 0% | 0% | 100% |
| 200° C., 60 min | 100% | 100% | 100% | 100% |

(Another Example of Baking Apparatus)

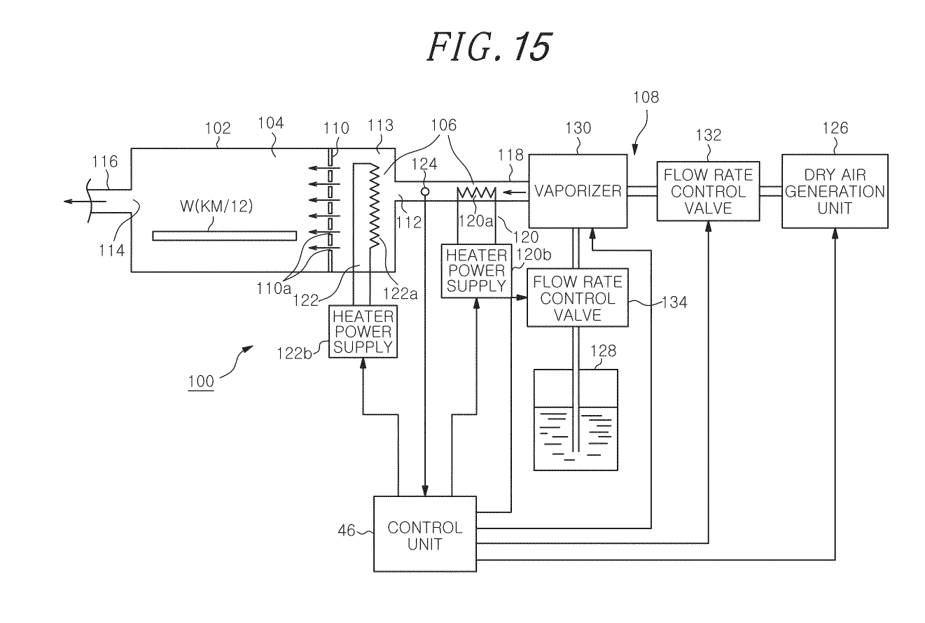

FIG. 15 shows another configuration example of the baking apparatus that can be used for the sintering process (2) in the above embodiment.

Similar to the baking apparatuses shown in FIGS. 4 and 5, a baking apparatus 100 shown in FIG. 15 is configured as a ventilation oven for performing a baking process while exchanging indoor air with exterior air. Specifically, the baking apparatus 100 includes a chamber 102 capable of accommodating as workpieces W (KM/12) a single or a plurality of semiconductor substrates 12 having, on one surface thereof, an ink coating film (KM) containing silver nanoparticles formed by the coating process (1), which can be loaded in and unloaded from the chamber 102; a ventilation unit 104 for discharging gas from the chamber 102 while introducing exterior air into the chamber 102; a temperature control mechanism 106 for controlling an atmosphere in the chamber 102 to a predetermined baking temperature; and a humidity control mechanism 108 for controlling a humidity in the chamber 102 to a set value ranging from about 30% to 50% RH (30° C.).

However, the ventilation unit 104, the temperature control mechanism 106 and the humidity control mechanism 108 of the baking apparatus 100 have configurations and functions different from those of the ventilation unit 34, the temperature control mechanism 36 and the humidity control mechanism 38 of the baking apparatus shown in FIG. 4. More specifically, the ventilation unit 104 includes a gas diffusion plate (or rectifying plate) 110 for uniformly diffusing air (humidified air having a temperature and a humidity controlled to a constant level, as will be described later) that has been introduced into the chamber 102. As shown in FIG. 15, the gas diffusion plate 110 is disposed at a side of the workpiece W (KM/12) horizontally provided at a predetermined position in the chamber 102 by a substrate support portion (not shown), i.e., between the workpiece W (KM/12) and an air inlet port 112 provided at one sidewall of the chamber 102, with the plate surface being set in a vertical direction. Here, a space 113 between the air inlet port 112 and the gas diffusion plate 110 forms a gas buffer space which temporarily stores the air introduced into the chamber 102.

The gas diffusion plate 110 has a plurality of gas injection openings 110a arranged uniformly, and the humidified air is rectified in a horizontal direction and injected at a uniform flow speed through the gas injection openings 110a. The air injected through the gas injection openings 110a passes the periphery of the workpiece W (KM/12) in the horizontal direction and flows toward a gas exhaust port 114 provided at a sidewall of the chamber which is opposite to the sidewall where the air inlet port 112 is formed. Then, the air is discharged to the outside of the chamber 102 from the gas exhaust port 114 through a gas exhaust line 116. Further, in order to form the above flow of the humidified air in the chamber 102, a fan (not shown) may be provided inside the chamber 102, or near the air inlet port 112 or the exhaust port 114.

The temperature control mechanism 106 includes a pre-heater 120 for preheating humidified air (exterior air) in the air duct 118 connected to the air inlet port 112 before the humidified air is introduced into the chamber 102, and a main heater 122 for heating the humidified air introduced into the gas buffer space 113 to a predetermined temperature before the humidified air is injected through the gas diffusion plate 110. The pre-heater 120 has a heat generation portion 120a provided in the air duct 118, and a heater power supply 120b for supplying power for heat generation to the heat generation portion 120a under the control of the control unit 46. The main heater 122 has a heat generation portion 122a provided in the gas buffer space 113, and a heater power supply 122b for supplying power for heat generation to the heat generation portion 122a under the control of the control unit 46.

In the air duct 118, a temperature-humidity sensor 124 is provided at a downstream side of the heat generation portion 120a of the pre-heater 120. The control unit 46 can control the heat generation amount of the pre-heater 120 such that the temperature value measured by the temperature-humidity sensor 124 becomes equal to a set temperature, and also can control the heat generation amount of the main heater 122 in accordance with the temperature value measured by the temperature-humidity sensor 124. Accordingly, the ambient temperature of the workpiece W (KM/12) or the atmosphere temperature in the chamber 102 can be controlled to a desired processing temperature.

The humidity control mechanism 108 includes a dry air generation unit 126 for generating dry air in the outside of the chamber 102, a container 128 for accommodating water, a vaporizer 130 for vaporizing water within the container 128 to generate mixed gas (humidified air) with the dry air from the dry air generation unit 126, a flow rate control valve 132 for controlling a flow rate of the dry air supplied from the dry air generation unit 126 to the vaporizer 130, a flow rate control valve 134 for controlling a flow rate of the water supplied from the container 128 to the vaporizer 130, the temperature-humidity sensor 124 for measuring a temperature and a humidity of the mixed gas generated by the vaporizer 130, and a control unit 46 for controlling the respective components in the humidity control mechanism 108.

The vaporizer 130 has, e.g., a venturi tube, and generates the mixed gas by controlling a suction air flow rate and a suction water flow rate by the pressure reduction that occurs when the suction air flows through the venturi tube. The control unit 46 controls at least one of the water flow rate and the dry air flow rate to be supplied to the vaporizer 130 by using the flow rate control valves 132 and 134 such that the weight ratio between the water and the air in the mixed gas becomes equal to a set value, based on the temperature value and the humidity value measured by the temperature-humidity sensor 124.

Here, the temperature-humidity sensor 124 outputs the measured temperature value as a dry-bulb temperature and the measured humidity value as a relative humidity. The control unit 46 obtains a control amount indicating an absolute humidity and a specific weight of water/air with respect to the set value and the measured values indicating the dry-bulb temperature and the relative humidity, by referring to the data of the psychometric chart stored in an internal memory.

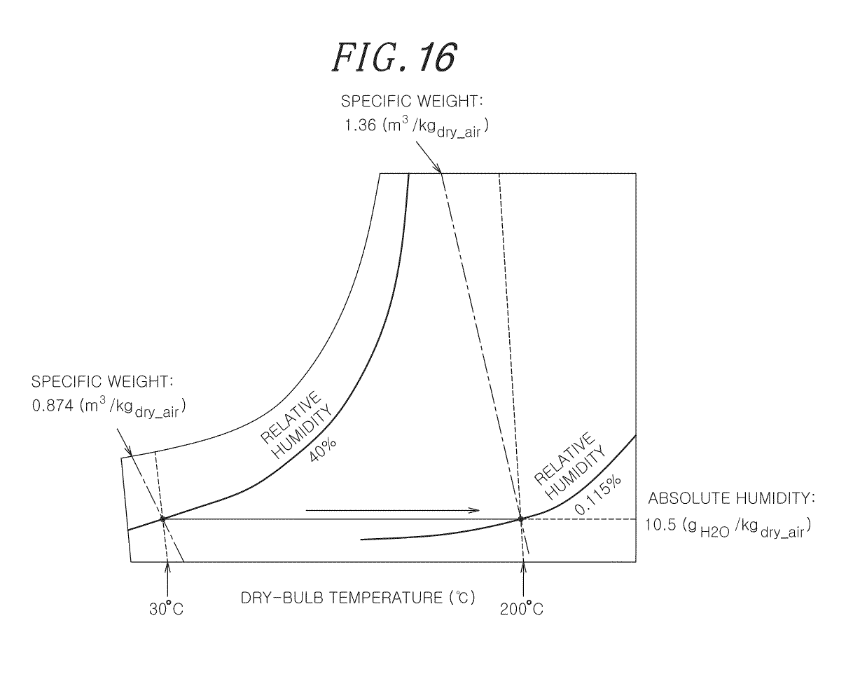

For example, as shown in FIG. 16, the psychometric chart published by ASHRAE (American Society of Heating, Refrigerating and Air-Conditioning engineers) shows that the air having 30° C. dry-bulb temperature and 40% relative humidity contains moisture of 10.5 g in dry air of 1 kg (10.5 g_{H2O}/kg_{dry}_{_{—}}ₐᵢᵣ) and the specific weight thereof is 0.874 m³/kg_{dry}_{_{—}}ₐᵢᵣ. Accordingly, in order to obtain humidified air (mixed gas) having 30° C. dry-bulb temperature and 40% relative humidity, it is preferable to supply water of 10.5 g to the dry air of 0.874 m³ at a predetermined time. To do so, the control unit 46 controls the flow rate control valves 132 and 134.

In that case, the humidified air (mixed gas) that satisfies the above condition is introduced into the chamber 102 and the sintering process (2) is performed at about 200° C. in the chamber 102. Then, as shown in FIG. 16, the relative humidity is decreased to about 0.115%. However, even if the temperature of the humidified air introduced at about 30° C. is increased to about 200° C. in the chamber 102, the absolute humidity is maintained at about 10.5 gₘ/k_{dry}_{_{—}}ₐᵢᵣ. Accordingly, the moisture content for the baking process in the humidified air supplied into the chamber 102 can be controlled to a constant level by the humidity control mechanism 108, regardless of increase in the temperature of the humidified air introduced into the chamber 102.

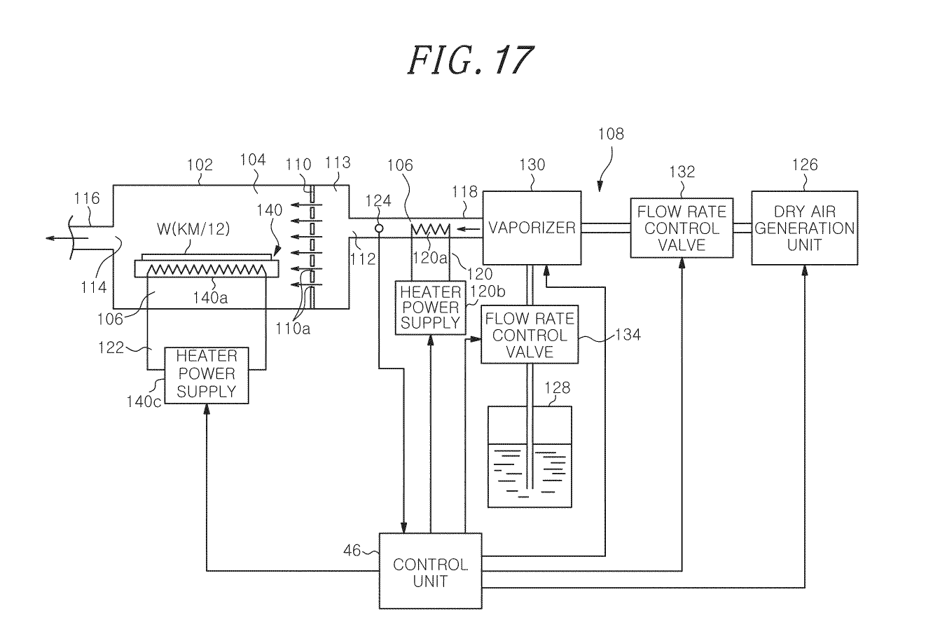

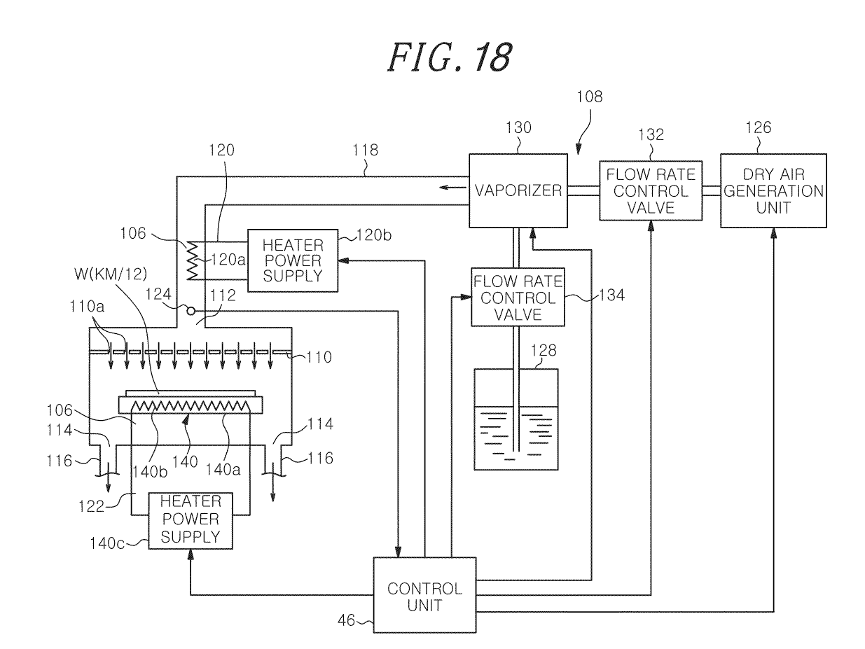

FIGS. 17 and 18 show modifications in which a hot plate 140 is provided in the chamber 102 in the baking apparatus shown in FIG. 15. The hot plate 140 includes a metal plate or mounting table 140a for mounting thereon a workpiece W (KM/12), a heating element 140b embedded in the mounting table 140a, and a heater power supply 140c for supplying power for heat generation to the heating element 140b under the control of the control unit 46. The hot plate 140 heats the workpiece W (KM/12) to a predetermined baking temperature by means of heat transfer.

The configuration example shown in FIG. 17 is of a side flow type similar to the configuration example shown in FIG. 15. In the configuration example of FIG. 17, the gas diffusion plate 110 is disposed at a side of the workpiece W (KM/12), and the humidified air is rectified and injected through the gas diffusion plate 110 in a direction parallel to the coating film forming surface of the workpiece W (KM/12).

The configuration example shown in FIG. 18 is of a downflow type. In this configuration example, the gas diffusion plate 110 is disposed immediately above the workpiece W (KM/12), and the humidified air is rectified and injected through the gas diffusion plate 100 in a direction perpendicular to the coating film forming surface (top surface) of the workpiece W (KM/12).

(Another Embodiment or Modification)

While the present invention has been described with respect to the embodiments and test examples, but is not limited to the above-described embodiments and thest examples, and it will be understood by those skilled in the art that various changes and modification may be made without departing from the scope of the invention.

For example, in the above embodiments and the test examples, there has been described the example in which a sintered silver coating film is formed on one surface of a semiconductor substrate by the method for forming the sintered silver coating film and the baking apparatus of the present invention. However, a sintered silver coating film may also be formed on one surface of a semiconductor package by the method for forming the sintered silver coating film and the baking apparatus of the present invention.

The spin coating method is preferablyused in the coating process (1) of the present invention. However, another coating method such as a printing method or the like may also be used.

In accordance with the method for forming a sintered silver coating film or the baking apparatus of the present invention, the above-described configuration makes it possible to form a sintered silver coating film used for a heat spreader which has excellent adhesivity and thermal conductivity on a semiconductor substrate or a semiconductor package.

In accordance with the semiconductor device of the present invention, the above-described configuration makes it possible to transfer the heat generated by the semiconductor substrate or the substrate package to the heat radiation portion via the sintered silver coating film having excellent adhesivity and thermal conductivity, so that the stable operation of the apparatus and the improvement of the reliability can be obtained.

While the invention has been shown and described with respect to the embodiments, it will be understood by those skilled in the art that various changes and modifications may be made without departing from the scope of the invention as defined in the following claims.

What is claimed is:

1. A method for forming a sintered silver coating film, for use as a heat spreader, on a semiconductor substrate or a semiconductor package, the method comprising
forming a coating film of an ink or paste containing silver nanoparticles on one surface of the semiconductor substrate or the substrate package; and
sintering the coating film by heating the coating film under an atmosphere of a humidity of 30% to 50% RH (30° C.) by a ventilation oven.

2. The method of claim 1, wherein the humidity in said sintering the coating film is in a range from 35% to 45% RH (30° C.).

3. The method of claim 1, wherein a heating temperature in said sintering the coating film is equal to or higher than 100° C.

4. The method of claim 1, wherein a heating temperature in said sintering the coating film is in a range from 100° C. to 250° C.

5. The method of claim 1, wherein the semiconductor substrate is a silicon substrate, and a surface of the silicon substrate on which the sintered silver coating film is to be formed is exposed in a bare state.

6. The method of claim 1, wherein the surface of the semiconductor substrate on which the sintered silver coating film is to be formed is coated with an inorganic film containing silicon.

7. The method of claim 1, wherein the ink or paste contains silver ultrafine particles coated with alkylamine-based protective molecules.

8. A baking apparatus for baking a coating film of an ink or paste containing silver nanoparticles which is formed on a semiconductor substrate or a semiconductor package, the baking apparatus comprising:
a chamber configured to accommodate the semiconductor substrate or the semiconductor package;
a ventilation unit configured to discharge air in the chamber by introducing exterior air into the chamber;
a temperature control mechanism configured to control a heating temperature of the semiconductor substrate or the semiconductor package in the chamber to a predetermined baking temperature; and
a humidity control mechanism configured to control a humidity in the chamber to be in a range from 30% to 50% RH (30° C.).

9. The baking apparatus of claim 8, wherein the ventilation unit includes:
a first port through which the exterior air is introduced into the chamber and a second port through which the air in the chamber is exhausted, the first port and the second port provided at different walls of the chamber; and
a fan configured to move air from the first port to the second port in the chamber.

10. The baking apparatus of claim 8, wherein the ventilation unit includes a gas diffusion plate configured to uniformly diffuse air introduced into the chamber.

11. The baking apparatus of claim 10, wherein the gas diffusion plate is disposed at a side of the semiconductor substrate or the semiconductor package in the chamber, and the air is rectified and injected through the gas diffusion plate in a direction parallel to a surface of the semiconductor substrate or the semiconductor package on which the coating film is formed.

12. The baking apparatus of claim 10, wherein the gas diffusion plate is provided above the semiconductor substrate or the semiconductor package in the chamber, and the air is rectified and injected through the gas diffusion plate in a direction perpendicular to a surface of the semiconductor substrate or the semiconductor package on which the coating film is formed.

13. The baking apparatus of claim 8, wherein the temperature control mechanism includes a first heater configured to preheat the exterior air before the exterior air is introduced into the chamber.

14. The baking apparatus of claim 13, wherein the temperature control mechanism further includes:
a first temperature measuring unit configured to measure a temperature of the exterior air before the exterior air is introduced into the chamber; and
a first temperature control unit configured to control a heat radiation amount of the first heater such that a temperature measurement value obtained by the first temperature measuring unit becomes equal to a first set temperature value.

15. The baking apparatus of claim 8, wherein the temperature control mechanism includes a second heater configured to heat air in the chamber.

16. The baking apparatus of claim 15, wherein the temperature control mechanism further includes:
a second temperature measuring unit configured to measure a temperature of an atmosphere in the chamber; and
a second temperature control unit configured to control a heat radiation amount of the second heater such that a measured temperature value obtained by the second temperature measuring unit becomes equal to a second set temperature value.

17. The baking apparatus of claim 8, further comprising:
a hot plate configured to heat the semiconductor substrate or the semiconductor package mounted on the hot plate in the chamber.

18. The baking apparatus of claim 8, wherein the humidity control mechanism includes:
a dry air generation unit configured to generate dry air;
a humidifier configured to humidify the air generated by the dry air generation unit before the air is introduced into the chamber;
a humidity measuring unit configured to measure humidity in the chamber; and
a humidity control unit configured to control an output of at least one of the dry air generation unit and the humidifier such that a measured humidity value obtained by the humidity measuring unit becomes equal to a set humidity value.

19. The baking apparatus of claim 8, wherein the humidity control mechanism includes:
a dry air generation unit configured to generate dry air;
a humidifier configured to humidify the air generated by the dry air generation unit before the air is introduced into the chamber;
a moisture content measuring unit configured to measure a moisture content of the air humidified by the humidifier; and
a humidity control unit configured to control an output of at least one of the dry air generating unit and the humidifier such that a measured moisture content value obtained by the moisture content measuring unit becomes equal to a set moisture content value.

20. The baking apparatus of claim 8, wherein the humidity control mechanism includes:
a dry air generation unit configured to generate dry air;
a vaporizer configured to vaporize water to generate mixed gas with the dry air from the dry air generation unit;
a first flow rate control valve configured to control a flow rate of the dry air supplied from the dry air generation unit to the vaporizer;
a second flow rate control valve configured to control a flow rate of the water supplied to the vaporizer;
a temperature-humidity sensor configured to measure a temperature and a humidity of the mixed gas generated by the vaporizer; and
a humidity control unit configured to control at least one of flow rates of the dry air and the water supplied to the vaporizer through the first and the second flow rate control valve such that a weight ratio between the water and the air in the mixed gas becomes a set value, based on a measured temperature value and a measured humidity value obtained by the temperature-humidity sensor.

21. The baking apparatus of claim 18, wherein the humidity control mechanism includes an air duct through which the air humidified by the humidifier is moved to the chamber.

22. A semiconductor device comprising:
a sintered silver coating film formed on a semiconductor substrate or a semiconductor package by the method for forming the sintered silver coating film which is described in claim 1; and
a heat radiation portion coupled to the sintered silver coating film.
